(19) United States
(12) Patent Application Publication
(10) Pub. No.: US 2011/0216596 A1
(43) Pub. Date: Sep. 8, 2011

(54) Reliability Protection for Non-Volatile Memories

(75) Inventor: Jeong Y. Choi, Palo Alto, CA (US)

(73) Assignee: Mosys, Inc., Sunnyvale, CA (US)

(21) Appl. No.: 12/717,301

(22) Filed: Mar. 4, 2010

(51) Int. Cl. G11C 16/04; H01L 29/788

(52) U.S. Cl. 365/185.18; 257/316; 257/E29.3

(57) ABSTRACT

A non-volatile memory cell having enhanced protection against mobile ions. The electric field within the memory cell is controlled in a manner that minimizes migration of mobile ions toward the floating gate. Each conductive layer in the memory cell is biased to reduce the flow of mobile ions toward the floating gate. The memory cell is preferably manufactured using a conventional logic process.

### BACKGROUND OF THE INVENTION

Non-volatile memory devices may be fabricated with either single or multiple polysilicon layers using a conventional logic process. As used herein, a conventional logic process is defined as a semiconductor process that implements twin-well or triple well technology and uses only one or more layers of polysilicon. The floating gates in a non-volatile memory store electrical charge. Considerable efforts have been directed toward preventing charge loss through the charge-injection oxide. However, charge loss can occur when mobile ions permeate the charge storage area of non-volatile devices.

In some cases, mobile ions move from the interlevel dielectric layers which leads to severe charge loss at high temperatures. The mobile ion movement is due to the presence of the electric field formed by the charge stored in the floating gate and the biases applied during operation or standby. Usually small positive ions such as Na⁺and K⁺migrate from the upper layers of the chip toward the silicon substrate. Attracted by the cells that have a high threshold voltage (excess negative charge on the floating gate), the ions move toward the floating gates of these cells and ultimately neutralize the effect of electrons within the floating gates. Consequently, the mobile ion migration cancels the negative charges on the floating gate, resulting in superficial charge loss and data retention failures.

Under certain bias conditions, the movement of mobile ions toward the floating gate may accelerate, causing devices to fail HTOL (High Temperature Operating Life) tests. For example, in the case where the first metal layer is used to route a control gate signal, mobile ions will accelerate toward the floating gate when the control gate is biased at a high voltage. Because the HTOL failure is accelerated as a result of such bias, the reliability failure is not always predictable during wafer sort or wafer-level data retention testing.

Single-poly cells and cells having a large portion of their floating gate uncovered by the control gate are more susceptible to charge loss. As devices scale downward, they become more vulnerable to failure from mobile ions, since the number of electrons stored on the floating gate scales with the cell dimension scaling. One way to counteract mobile ions is through the use of a gettering layer.

A gettering layer involves incorporating phosphorus in dielectric layers to immobilize mobile ions. However, a gettering layer may not completely confine mobile ions within the layer. Despite the use of gettering layers, mobile ions still affect the device characteristics and result in data retention failures. With the continued increase in cell density there is an increase in vulnerability to charge loss. Therefore, a need exists for a non-volatile memory cell that has an improved resistance to data retention failures.

### SUMMARY

The present invention provides a non-volatile memory cell with enhanced reliability protection during operation. The memory cell includes a semiconductor substrate having a tunnel oxide layer, upon which is disposed a floating gate. A control gate is separated from the floating gate by a dielectric layer. Two conductive layers (“conductors”) are included in the memory cell, each having a bias voltage different from the other during operation. Further, the bias polarity carried by a pair of conductors during standby may be opposite that of a pair of conductors during a read operation. For example, in a selected state, the first conductor may have a high polarity and the second conductor a low polarity. Then, in an unselected state, the first conductor will have a low polarity and the second conductor a high polarity. During standby, the memory cells are typically unselected, and will be biased in accordance with the predetermined bias polarity level.

Each conductor is connected to either a source/drain region or a control gate, depending on their respective bias voltages during standby. During a standby mode, if the first conductor is biased at a lower voltage relative to the second conductor, then the first conductor is connected to the source/drain region and the second conductor is connected to the control gate.

The invention also provides a non-volatile memory cell having a floating gate that is configured to operate at a potential greater than the bias voltage of the first conductor. With this configuration, mobile ions are influenced to migrate away from the floating gate. As a result, the non-volatile memories of the invention exhibit enhanced data reliability.

In another embodiment, the invention pertains to a non-volatile memory system having an array of memory cells, wherein each memory cell includes an access transistor having source/drain regions and a capacitor structure which preferably has a diffusion region of opposite conductivity to the source/drain regions. The access transistor and capacitor structure share a common floating gate. The other electrode of the capacitor is a control gate, whose bias modulates the conductivity of the access transistor by coupling its bias to the floating gate determined by the capacitive coupling ratio between the access transistor and the capacitor.

Each control gate in the memory system is separated from the floating gate by a dielectric region. If the bit line is biased at a higher voltage than the control gate, then a first conductor is connected to the control gate and the second conductor serves as the bit line. In this embodiment, the bit line is connected to a source/drain region of the access transistor.

The invention is also directed to a structure for a non-volatile memory system composed of an array of memory cells in which each cell includes an access transistor and a capacitor that share a common floating gate. Specifically, each memory cell has a structure that disposes a bit line between the floating gate and the control gate line. In this embodiment, the bit line is biased at a higher voltage than the control gate, such that a first conductor constitutes the control gate line and is connected to the control gate while a second conductor constitutes the bit line and is connected to one of the source/drain regions.

The present invention will be more fully understood in view of the following description and drawings.

### BRIEF DESCRIPTION OF THE DRAWINGS

FIG. 1 is a top view of a non-volatile memory cell having a PMOS access transistor and an NMOS coupling gate in accordance with one embodiment of the present invention;

FIGS. 2A and 2B are cross sections of the non-volatile memory cell of FIG. 1;

FIG. 3 is a schematic diagram of an array of the non-volatile memory cells of FIG. 2;

FIGS. 4A, 4B and 4C illustrate electrical connections that enhance the reliability of the memory cell of the present invention; and

FIG. 5 is a cross sectional view of a double-poly non-volatile memory cell.

### DETAILED DESCRIPTION

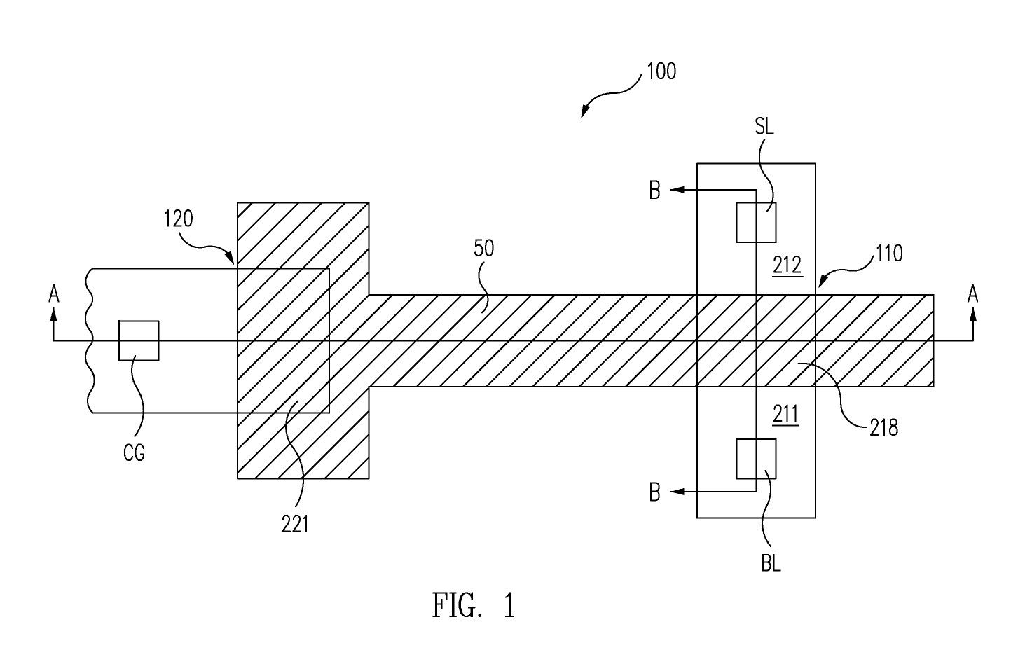

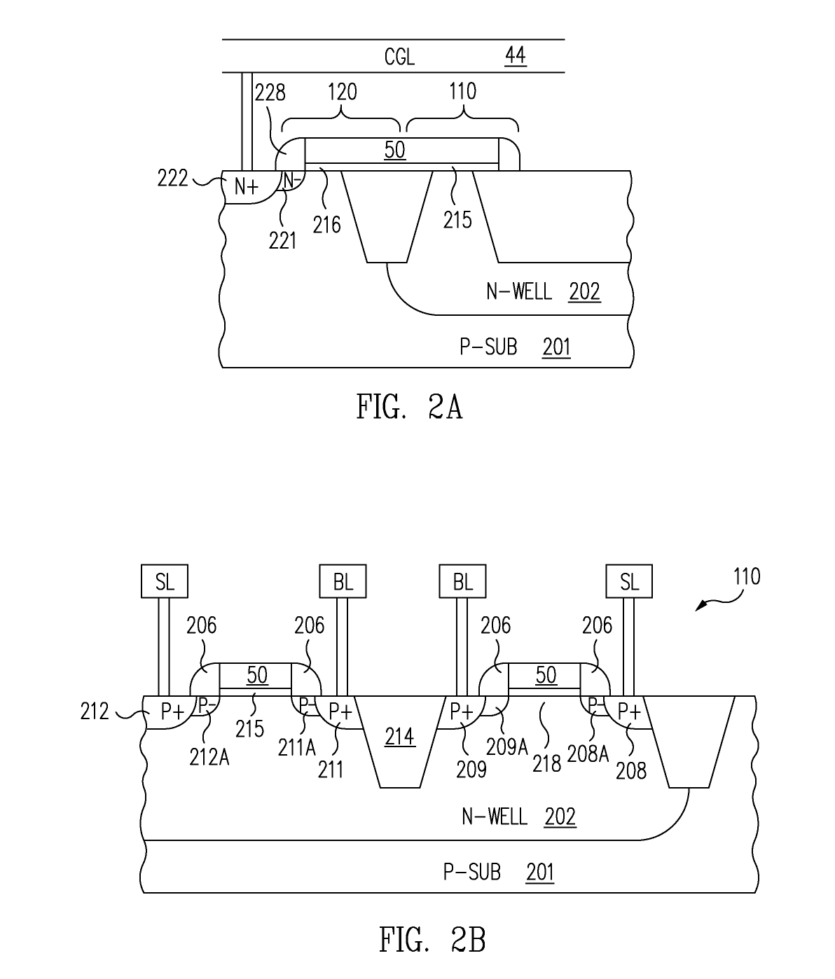

FIG. 1 is a top layout view of a non-volatile memory cell 100 in accordance with one embodiment of the present invention. Floating gate 50 extends over access transistor 110 at one end, and over capacitor 120 at the opposite end. Source line and bit line contacts flank the channel region 218 of access transistor 110. A control gate (CG) for controlling the conductivity of memory cell 100 is shown adjacent to coupling region 221. FIG. 2A is a sectional view of capacitor 120 of FIG. 1 along section line A--A.

A control gate line (CGL) supplies a bias voltage to the control gate through a connection that is shown in FIG. 2A. CGL 44 operates as a word line in a 1T cell. In the described example, non-volatile memory cell 100 is fabricated in a p-type mono-crystalline semiconductor substrate 201 (see FIG. 2A). FIG. 2A illustrates a cross-sectional view of capacitor 120 of FIG. 1. Floating gate extends over p-type substrate 201 and n-type coupling region 221. N-type coupling region 221 is coupled to n+region 222. N-type regions 221-222, capacitor oxide 216 and floating gate 50 form an NMOS capacitor structure 120. NMOS capacitor 120 couples the bias at n+region 222 to floating gate 50. N-type coupling region 221 is self-aligned with the edge of floating gate 50. This self-alignment is accomplished by implanting an n-type impurity using the edge of floating gate 50 as a mask, and then diffusing the impurity under the floating gate using an annealing step. N-type coupling region 221 is formed at the same time as the source and drain regions of NMOS logic transistors (not shown). Accordingly, no additional step is required to form n-type coupling region 221.

FIG. 2B is a cross sectional view of the access transistor 110 of FIG. 1 along section line B-B of FIG. 1. In FIG. 2B, substrate 201 is a p-type semiconductor. Non-volatile memory cell 100 of FIG. 1 includes a PMOS access transistor 110. Access transistor 110 includes p-type source region 211 and p-type drain region 212, which are formed in n-well 202. In FIG. 2B, source region 211 includes lightly doped source 211A and p+source contact region 211. Source region 211 is connected to a bit line (BL) and drain region 212 is connected to a source line (SL). However, the connections may be reversed, such that source region 211 is connected to a source line, and drain region 212 may instead be connected to a bit line. Drain region 212 includes lightly doped drain 212A and p+drain contact region 212. An n-type channel region 218 is located between source region 211 and drain region 212. Field oxide 214 is located between the source and drain regions as illustrated (FIG. 2B). Field oxide 214 is planarized, such that the upper surface of field oxide 214 and the upper surface of substrate 201 are located in substantially the same plane. A thin tunnel oxide layer 215 is located over the channel region 218. Tunnel oxide layer 215 has the same thickness as the gate oxide layers used in the logic transistors (not shown) fabricated in substrate 201. A conductively doped polycrystalline silicon floating gate 50 is located over thin tunnel oxide 215. Sidewall spacers 206 and 228 are typically formed from silicon nitride or silicon oxide, are located at the edges of floating gate 50.

Similarly, control gate 222 is self-aligned with the edge of sidewall spacer 228. This self-alignment is accomplished by implanting an n-type impurity using the edge of sidewall spacer 218 as a mask, and then diffusing the impurity under the sidewall spacer using an anneal step. The control gate 222 is formed at the same time as the n+contact regions of NMOS logic transistors (not shown). Accordingly, no additional step is required to form n+control gate 222.

The total capacitance of NMOS coupling capacitor structure 120 is preferably significantly larger than the gate capacitance of the PMOS access transistor 110. In preferred embodiments, the capacitance of NMOS coupling capacitor structure 120 is about four to ten times larger than the gate capacitance of PMOS access transistor 110. Non-volatile memory cell 100 can be fabricated using a conventional logic process, without any process modifications or special implants.

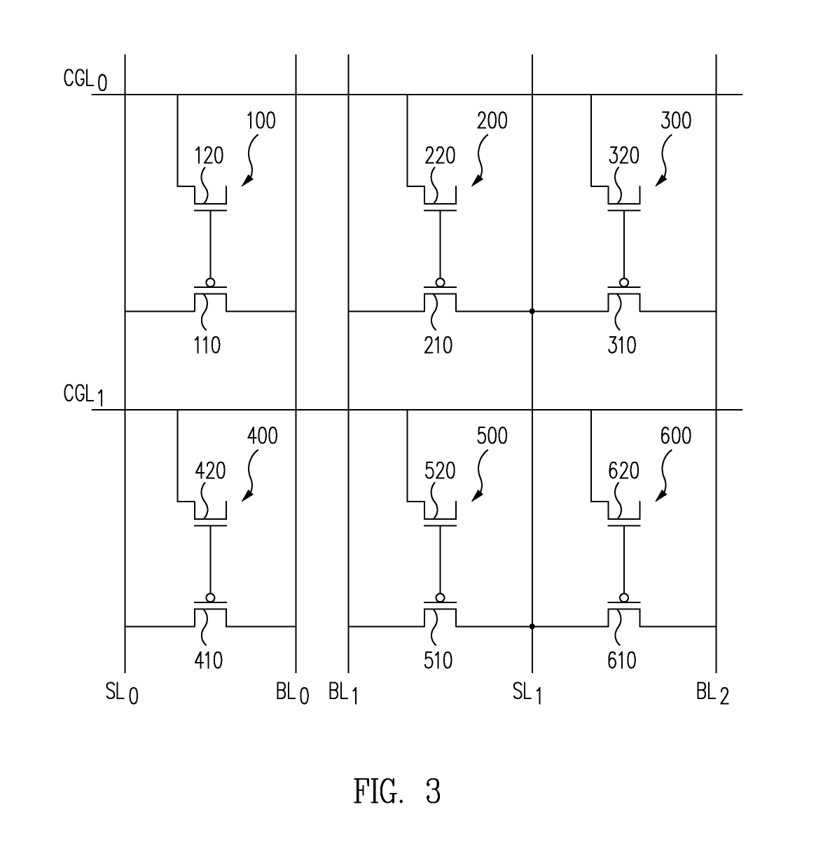

FIG. 3 is a schematic diagram of a 2×3 array of non-volatile memory cells 100, 200, 300, 400, 500 and 600. Non-volatile memory cells 200, 300, 400, 500 and 600 are identical to above-described non-volatile memory cell 100. Thus, non-volatile memory cells 200, 300,400, 500 and 600 include PMOS access transistors 210, 310, 410, 510 and 610 respectively, and NMOS capacitor structures 220, 320, 420, 520 and 620, respectively. The sources of PMOS access transistors 110 and 410 are commonly connected to a first bit line BL₀. The sources of access transistors 210 and 510 are commonly connected to a second bit line BL₁. The drains of PMOS access transistors 110 and 410 are commonly connected to a first source line SL₀ whereas, the drains of PMOS access transistors 210 and 510 are commonly connected to a second source line SL₁. The drains of access transistor 310 and 610 may be connected to a separate source line (not shown) parallel to SL₁. Alternatively the drains of access transistors 310 and 610 may share source line SL1 with the drains of access transistors 210 and 510. In addition, the sources of transistors 310 and 610 are connected to BL₂. It is not essential for source lines to run vertically as shown in FIG. 3. The source lines may instead run horizontally. For example, cells 100, 200, and 300 may share one source line along a horizontal axis, and cells 400, 500 and 600 may share a different source line along a second horizontal axis. Alternatively, a source line can be shared by two adjacent rows of cells. In this embodiment, an even and an odd row of cells along a common bit line may share one drain contact. NMOS capacitor structures 120, 220 and 320 are commonly connected to a first control gate line CGL₀. Similarly, NMOS capacitor structures 420, 520 and 620 are commonly connected to a second control gate line CGL₁. Although the described array has two rows and three columns, it is understood that arrays having other sizes can be implemented by one of ordinary skill in the art.

In one embodiment, non-volatile memory cells 200 and 300 may be read by holding CGL₀ at 0 Volts, source lines SL₀-SL₁ at 0 V (or some other voltage level to suppress leakage current), n-well 202 at 1.0 V, and p-type substrate 201 at 0 V. Bit lines BL₀-BL₁ are pre-charged to 1.0 V (or some other voltage higher than the control gate bias). Memory cells 200 and 300 may instead be read by precharging the source lines to 1 V, and the bit lines to 0 V. Under these conditions, read current will flow through the access transistors of programmed cells, without disturbing the data stored in the access transistors of non-programmed (erased) cells.

The control gate line CGL₁ associated with the unselected cells is held at a positive voltage such as 4V in the normal read mode. A 4V voltage is sufficient to turn off access transistors 410, 510, and 610. When access transistors 410, 510, 610, are turned off current will not flow through these transistors into bit lines BL₀ and BL₁, even if any of these transistors are programmed. As a result, cells 400, 500 and 600 do not interfere with the bit line signals from selected cells 100, 200 and 300.

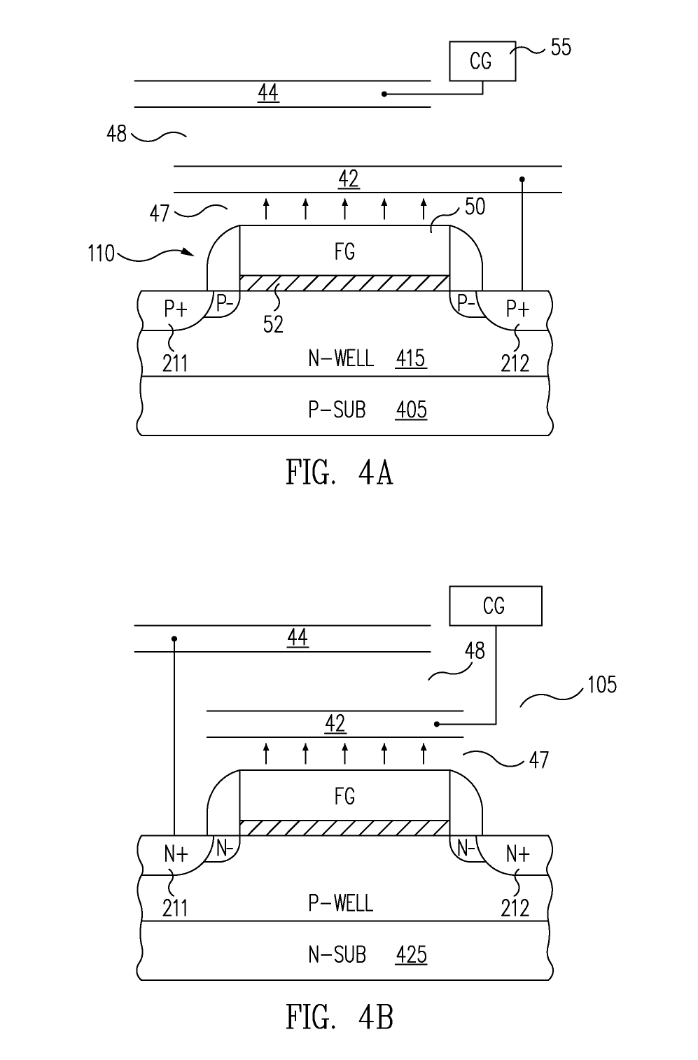

FIG. 4A illustrates a PMOS access transistor 110 located in an n-well that is in a p-substrate. Floating gate 50 is disposed on tunnel oxide layer 52, and bit line 42 is separated from floating gate 50 by dielectric region 47. Also shown in FIG. 4A is dielectric region 48, which separates bit line 42 from second conductor 44. To minimize the impact of mobile ions on the floating gate during standby, the bias voltages of the conductors during standby determine which conductor is connected to which cell region. In addition, the speed, power, and reliability desired for a specific memory device will determine the appropriate bias to select for the bit line. Specifically, FIG. 4A illustrates the situation where bit line 42 is biased between 1V-2V. In this embodiment, N-well 415 is preferably biased at the same or higher bias than the bit line in order to avoid forward-biasing the P+/N-well diode. Second conductor 44 is preferably biased at a voltage sufficient to turn off unselected programmed cells. The above bias conditions for the cell shown in FIG. 4A result in bit line 42 having a lower bias voltage than conductor 44 (typically 4V or higher during standby). In accordance with the invention, bit line 42 is connected to source or drain region 212, and conductor 44 is connected to control gate 55. Then, when memory cell 110 is programmed, floating gate 50 has a higher potential during standby than the bit line bias. Consequently, the electric field between the lower positively-biased conductor 42 and floating gate 50 is reduced compared to the electric field generated by the voltage difference between the control gate and the floating gate.

In FIG. 4A, mobile ions within the memory cell migrate in the direction shown since floating gate 50 has a higher voltage than conductor 42 (bit line). As a result, mobile ions migrate away from the floating gate and avoid significantly disturbing its contents.

During a standby operation for the PMOS transistor of FIG. 4A, n-well 415 is held at 1V and p-type substrate 405 is held at 0 V. Cells which are in a programmed state preferably have the electric field potential of floating gate 50 at a potential higher than 1V (the BL bias), bit line 42 is biased at 1V, and second conductor (control gate line) 44 is biased at 0 V. Since the floating gate in the PMOS transistor is more positive than bit line 42 in FIG. 4A, mobile ions in dielectric region 47 will be forced by the electric field to migrate away from the floating gate. Mobile ions also exist within dielectric region 48. Ions in the electric field of region 48 travel downward away from the control gate because conductor 44 has a higher potential than bit line 42. However, such ions are prevented from accumulating around floating gate 50 because of the field created by the voltage difference between floating gate 50 and bit line 42. Consequently, mobile ions will not accumulate around floating gate 50 of the PMOS transistor during standby.

The standby operation for NMOS transistor 105 will now be described in conjunction with FIG. 4B. Memory cell 105 is programmed to provide the floating gate with a potential higher than the control gate during standby. In one embodiment, the cells in their programmed state are configured to place floating gate 50 at a potential between 1-2V. Preferably, control gate line 42 is biased at 0V during standby. Under the above conditions, the electric field (shown by arrows) causes ions to migrate away from floating gate 50. During a read operation, however, the selected control gate line has a potential of 4V, which is higher than the bit line bias and the floating gate. The voltage difference between the control gate line and the floating gate will cause a slight migration of ions toward the floating gate, but the ions will migrate in the opposite direction, i.e., away from the floating gate, for a much longer period when unselected or during a standby.

The invention is also directed to a non-volatile memory structure having two conductors that are biased differently during a standby operation. The conductors may be fabricated out of metal or polysilicon. However, it is not essential to use the same material to fabricate each of the conductors.

In a preferred embodiment, the first conductor 42 is a bit line, and the second conductor 44 is a control gate line. However, it is understood that the roles of conductor 42 and conductor 44 may be reversed, depending on what regions these conductors are connected to in the memory cell.

The read operation for NMOS access transistor 105 in accordance with another embodiment of the present invention will now be described in accordance with FIG. 4B. Again, floating gate 50 has an electric potential usually higher than 1V. If conductor 42 is biased at 0V and conductor 44 is biased at 1V, then each conductor will have the electrical connections shown in FIG. 4B. In this embodiment, conductor 42 functions as a CGL because it is connected to control gate 55, and conductor 44, functions as the bit line, as it is connected to the source or drain region 212. The cell conditions of FIG. 4B result in a reduced electric field between the lower positively biased conductor 44 and floating gate 50. This reduced electric field causes ions to migrate toward floating gate 50 during a read operation. Nevertheless, the reading of memory cell 105 is not expected to cause significant data retention failures, since the non-volatile device is not continually reading the same portions of the memory array. In addition, any charge loss is minimal for the cell of FIG. 4B because a read operation is generally interspersed with idle periods during which the memory device is in a standby mode.

In a read operation, the control gate lines are precharged to an unselected state. When the memory device receives an address for a specific CGL, the selected CGL is discharged to zero and maintained at zero for the first half of the clock cycle period. During the first half of the clock cycle, the read biases are applied to the selected cells until the memory switches to a nonselected state, and then biases the previously selected cells with the voltage for a standby operation during the second half of the same clock period. During the standby mode, the flow of mobile ions in the memory cell is opposite the flow that is present during a read mode. A read operation will occur in a substantially shorter time period than the time that elapses during standby. Thus, the migration of mobile ions toward the floating gate during a read will be immediately reversed by the electric field that is present in the standby mode. Accordingly, the invention will enhance the reliability of the stored data in a non-volatile memory regardless of whether a PMOS or NMOS access transistor is used for the memory cell.

FIG. 4C is similar to FIG. 4B, except for the provision of a P-well within a deep N-well. FIG. 4C will generally operate in the same manner as FIG. 4B.

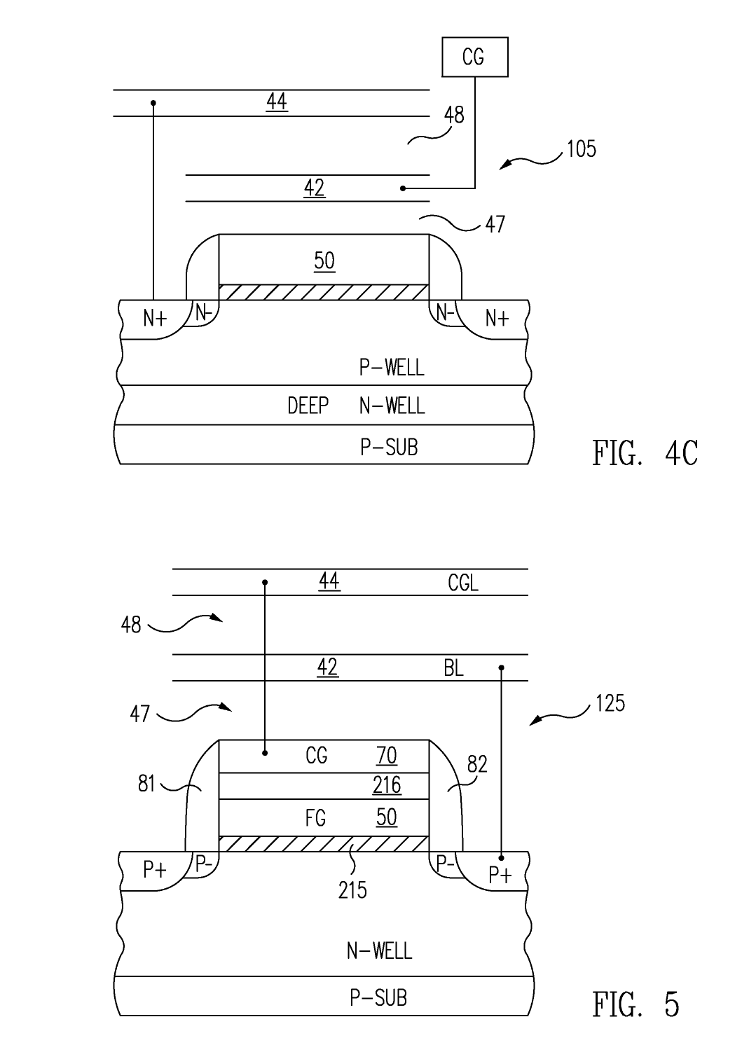

FIGS. 2A, 2B, 4A, 4B and 4C illustrate a memory cell having a single polysilicon layer. However, the invention may also be implemented using two or more polysilicon layers. FIG. 5 illustrates a memory cell with two polysilicon layers separated by dielectric layer 216. The first polysilicon layer forms floating gate 50, and the second polysilicon layer forms control gate 70. As in the earlier described embodiments, the memory cell has two dielectric regions 47 and 48. Mobile ions may exist in each of dielectric regions 47 and 48. In this embodiment, control gate 70 is connected to conductor 44 (control gate line) and source/drain region is connected to conductor 42 (bit line). Memory cell 125 has a smaller density then the cells of FIGS. 4A-4C. Memory cell 125 is also generally better protected from mobile ion effects than memory cell 105 or 110, due to spacers 81 and 82. The spacers in FIG. 5 completely surround the lateral portions of floating gate 50 to substantially prevent mobile ions from contacting the floating gate.

Although the invention has been described in connection with several examples, it is understood that this invention is not limited to the embodiments disclosed, but is capable of various modifications, which would be apparent to a person skilled in the art. For example, source contacts may be omitted from the memory array and provided at predetermined interface regions that are regularly spaced along row or column directions. Accordingly, the present invention is limited only by the following claims.

The invention claimed is:

1. A non-volatile memory cell comprising:
a semiconductor substrate having a tunnel oxide layer;
a floating gate disposed on said tunnel oxide layer;
a first conductive layer separated from said floating gate by a first dielectric layer;
a second conductive layer separated from said first conductive layer by a second dielectric layer, each conductive layer having a bias voltage different from the other;
a control gate separated from the floating gate by a dielectric region;
a source/drain region within said semiconductor substrate;
wherein if the source/drain region is biased at a lower voltage relative to said control gate during a standby operation, then the source/drain region is connected to the first conductive layer and the second conductive layer is connected to said control gate.

2. The non-volatile memory cell of claim 1, wherein the floating gate is fabricated with a single polysilicon layer process.

3. The non-volatile memory cell of claim 1, wherein the floating gate is fabricated with a double polysilicon layer process.

4. The non-volatile memory cell of claim 1, wherein the floating gate for a programmed cell is configured to operate at a potential greater than the bias voltage of the first conductive layer, thereby causing mobile ions to migrate in a direction away from the floating gate.

5. A non-volatile memory cell that includes a floating gate and a bit line, comprising programming the floating gate with a voltage potential that is higher than the bit line to cause mobile ions in the memory cell to migrate away from the floating gate during a standby operation.

6. A non-volatile memory system fabricated using a conventional logic process, the non-volatile memory system comprising:
a doped semiconductor substrate of a first conductivity type;
a doped well of a second conductivity type located in said semiconductor substrate;
a PMOS transistor located in said well, the PMOS transistor having a floating gate disposed over the semiconductor substrate;
a control gate separated from the floating gate by a dielectric region;
a first conductive layer separated from said floating gate by a first dielectric layer;
a second conductive layer separated from said first conductive layer by a second dielectric layer, wherein each of said conductive layers has a bias voltage different from the other;
wherein if the first source/drain region is biased at a lower voltage relative to said control gate during a standby operation, then said first conductive layer is connected to the source/drain region and the second conductive layer is connected to the control gate.

7. The non-volatile memory system of claim 6, further comprising an NMOS coupling capacitor wherein the NMOS coupling capacitor has a capacitance greater than the capacitance of the PMOS transistor.

8. The non-volatile memory system of claim 7, wherein the capacitance of the NMOS coupling capacitor is between about 4 to about 10 times greater than the capacitance of the PMOS transistor.

9. The non-volatile memory system of claim 6, wherein said well is an n-well positioned within a deep p-well.

10. The non-volatile memory system of claim 6, wherein the memory cell is fabricated from at least one polysilicon layer.

11. The non-volatile memory system of claim 6, wherein the floating gate is programmed to a potential greater than the bias voltage of the first conductive layer, thereby causing mobile ions to migrate in a direction away from the floating gate.

12. A non-volatile memory system fabricated using a conventional logic process, the non-volatile memory system comprising:
a doped semiconductor substrate of a first conductivity type;
a doped well of a second conductivity type located in said semiconductor substrate;
an NMOS transistor located in said well, the NMOS transistor having a floating gate disposed over the semiconductor substrate;
a first conductive layer separated from said floating gate by a first dielectric layer;
a second conductive layer separated from said first conductive layer by a second dielectric layer, wherein each of said conductive layers has a bias voltage different from the other;
wherein if the source/drain region is biased at a lower voltage relative to the control gate during a standby operation, then said first conductive layer is connected to the source/drain region, and the second conductive layer is connected to the control gate.

13. The non-volatile memory system of claim 12, further comprising a PMOS coupling capacitor wherein the PMOS coupling capacitor has a capacitance greater than the capacitance of the NMOS transistor.

14. The non-volatile memory system of claim 12, wherein the capacitance of the PMOS coupling capacitor is between about 4 to about 10 times greater than the capacitance of the NMOS transistor.

15. The non-volatile memory system of claim 12, wherein the floating gate is fabricated with at least one polysilicon layer.

16. A non-volatile memory system comprising:
an array of non-volatile memory cells, wherein each of the non-volatile memory cells includes an access transistor having source/drain regions of a first conductivity type and a capacitor structure having a diffusion region of a second conductivity type, opposite the first conductivity type, wherein the access transistor and capacitor structure share a common floating gate;
a control gate separated from the floating gate by a first dielectric region;
a bit line separated from the floating gate by a second dielectric region;
a control gate line located between said floating gate and said bit line, said bit line being biased at a higher voltage than the control gate line wherein the control gate line is connected to the control gate and the bit line is connected to one of the source/drain regions.

17. The non-volatile memory system of claim 16, wherein the floating gate is fabricated using a single polysilicon layer process.

18. The non-volatile memory system of claim 16, wherein the floating gate is fabricated using a double polysilicon layer process.
